(19) United States
(12) Patent Application Publication
(10) Pub. No.: US 2016/0268411 A1
(43) Pub. Date: Sep. 15, 2016

(54) HIGH ELECTRON MOBILITY TRANSISTOR (HEMT) AND METHOD OF PRODUCING THE SAME

(71) Applicant: Sumitomo Electric Industries, Ltd., Osaka-shi (JP)

(72) Inventor: Ken Nakata, Yokohama-shi (JP)

(21) Appl. No.: 15/065,532

(22) Filed: Mar. 9, 2016

(30) Foreign Application Priority Data
Mar. 10, 2015 (JP) 2015-047322

(51) Int. Cl. H01L 29/778; H01L 29/66; H01L 29/10; H01L 21/02; H01L 29/20; H01L 29/205

(52) U.S. Cl. CPC H01L 29/7787; H01L 29/2003; H01L 29/205; H01L 29/1029; H01L 21/02458; H01L 21/0254; H01L 29/66462

(57) ABSTRACT

A high electron mobility transistor (HEMT) primarily made of nitride semiconductor materials is disclosed. The HEMT includes, on a substrate, a buffer layer, a channel layer, and a barrier layer. The cannel layer is dual layers each made of GaN. The first GaN layer closer to the buffer layer has a carbon concentration [C] less than 10¹⁶ cm⁻³, while, the second layer also made of GaN layer having a carbon concentration [C] greater than 2×10¹⁶ cm³. The channel layer has a total thickness greater than 400 nm but less than 1000 nm.

### BACKGROUND OF THE INVENTION

1. Field of the Invention

The present application relates to a high electron mobility transistor (HEMT), in particular, a HEMT made of nitride semiconductor materials, and a method of producing the HEMT.

2. Related Background Arts

Recently, a HEMT made of nitride semiconductor materials has been developed and practically used in applications. Such a HEMT provides a buffer layer, a channel layer, and a barrier layer sequentially epitaxially grown on a substrate. A Japanese Patent Application lade open No. JP2008-251966A has disclosed a HEMT having a buffer layer made of AlGaN or GaN doped with iron (Fe), and a channel layer made of i-GaN layer with a thickness of 2.5 μm to make the two-dimensional electron gas (2-DEG) apart from irons in the buffer layer.

Another Japanese Patent application laid open No. JP2009-021279A has discloses a HEMT having a buffer layer includes a composite layer of AlGaN and InGaN, AlN layer, and a GaN layer, where the GaN layer has a carbon concentration of 0.3˜2.0×10¹⁷ cm⁻³ and resistivity greater than 1×10⁷ Ω·cm. Still another Japanese Patent application laid open No. 2006-114652A has disclosed a HEMT having a buffer layer made of un-doped AlN and un-doped GaN, a channel layer made of another un-doped GaN, and a barrier layer made of AlGaN. The HEMT disclosed therein has grown these layers on a substrate at a growth pressure (100 Torr) common to all layers. The AlN layer and two GaN layers have thicknesses of 0.3 μm, 2 μm, and 0.1 μm respectively.

### SUMMARY OF THE INVENTION

One aspect of the present application relates to a high electron-mobility transistor (HEMT) that comprises a buffer layer and a channel layer. The channel layer includes a first semiconductor layer and a second semiconductor layer. The first semiconductor layer maybe configured to be provided on the barrier layer, to be made of gallium nitride (GaN), and to have a carbon concentration [C] less than 1×10¹⁶ cm⁻³. The second semiconductor layer may be configured to be provided on the first semiconductor layer, to be made of GaN, and to have a carbon concentration greater than 2×10¹⁶ cm⁻³. A feature of the HEMT of the present invention is that, the channel layer has a total thickness greater than 400 nm but less than 1000 nm. The first semiconductor layer may have a thickness greater than 100 nm, while, the second semiconductor layer may have a thickness greater than 200 nm.

Another aspect of the present application relates to a method to produce a high electron-mobility transistor primarily made of nitride semiconductor materials. The method includes steps of: (1) growing a buffer layer on a substrate, (2) growing a first semiconductor layer made of GaN as a part of a channel layer, and (3) growing a second semiconductor layer also made of GaN as another part of the channel layer. A feature of the process of the present invention is that the growth pressure of the second GaN layer is at least 50 Torr lower than that for the first GaN layer when the grown temperature for the second GaN layer is comparable to that for the first GaN layer; or the growth temperature for the second GaN layer is at least 40° C. lower than that for the first GaN layer when the growth pressure for the second GaN layer is comparable to that for the first GaN layer.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a cross section of a high electron mobility transistor (HEMT) according to an embodiment of the present application;

FIG. 2A to 2C show processes of the HEMT shown in FIG. 1;

FIGS. 3A and 3B show processes subsequent to those shown in FIGS. 2A to 2C;

FIG. 4 shows pit densities observed in a surface of the AlGaN barrier layer against the thickness of the first GaN layer; and

FIG. 5 shows a leak current of the second GaN layer against the thickness thereof.

### DESCRIPTION OF EMBODIMENTS

A high electron mobility transistor (HEMT), in particular, a HEMT made of nitride semiconductor materials has been requested to reduce a leak current thereof in order to enhance the high-frequency performance and power extracted therefrom. Techniques to reduce the leak current to increase the resistivity of a buffer layer by, for instance, doping irons (Fe), increasing carbon concentration [C], and/or increasing a thickness of AlN layer, have been disclosed in those aforementioned Japanese prior arts. Also, the techniques disclosed in those prior arts have accompanied with increasing thickness of the channel layer made of GaN and/or AlGaN, which inevitably accompanies with an elongated process time and an excess source materials. Thickened layers also results in an enhanced bend of the grown layers. Techniques not accompanying with thickening semiconductor layers are preferable.

From other viewpoints of enhancing performance and yield of a HEMT, the pit defect appearing on a surface of the epitaxially grown layer has been continuously requested to be small as possible. The pit density strongly depends on conditions of the epitaxial growth. Setting the growth conditions so as to thin the grown layer, the pit density is hard to be smaller. Accordingly, the growth conditions to increase the thickness of the grown layer are preferably selected. However, as explained, a thicker grown layer inevitably accompanies with an increased leak current.

The growth conditions where (1) the growth rate for the lateral direction becomes larger compared with that for the vertical direction, (2) the growth temperature is set comparably higher, and (3) the growth pressure is set comparably higher may reduce the pit density by burying the pit. However, these conditions accompany with the reduction of the carbon concentration [C] in the grown layer and resultantly increase the leak current. The reduction of the leak current has been inconsistent with the reduction of the pit density.

Next, some preferable embodiment according to the present application will be described as referring to drawings. In the description of the drawings, numerals or symbols same with or similar to each other will refer to elements same with or similar to each other without duplicating explanations.

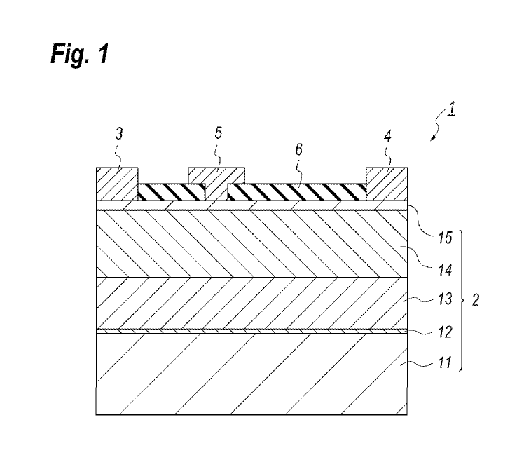

FIG. 1 shows a cross section of a high electron mobility transistor (HEMT) according to an embodiment of the present application. The HEMT 1 includes semiconductor layers 2, a source electrode 3, a drain electrode 4, a gate electrode 5, and a passivation film 6. The semiconductor layers 2 include a substrate 11, an AlN layer 12, a first GaN layer 13, a second GaN layer 14, and a barrier layer 15. The second GaN layer 14 forms a two-dimensional electron gas (2-DEG) in a vicinity of the interface against the barrier layer 15, which becomes a channel for the HEMT 1.

The source electrode 3 and the drain electrode 4, which are provided on the barrier layer 15 and operate as ohmic electrodes, may be made of metal stack including titanium (Ti) and aluminum (Al), where Ti is in contact to the barrier layer 15. The gate electrode 5, which is also provided on the barrier layer 15 between the source electrode 3 and the drain electrode 4, may be made of another metal stack of nickel (Ni) and gold (Au), where Ni is in contact to the barrier layer 15.

The passivation film 6, which is provided on the barrier layer 15, has openings corresponding to the source electrode 4, the drain electrode 4, and the gate electrode rode 6, may passivate and protect the surface of the barrier layer 15 between the electrodes, 3 to 5. The passivation film 6 may be made of silicon nitride (SiN).

The substrate 11, which is a base for the epitaxial growth, may be made of one of silicon (Si), silicon carbide (SiC), sapphire (Al₂O₃), and diamond (C). The HEMT 1 of the present embodiment provides the substrate 11 made of SiC. Epitaxially grown in the substrate 11 are AlN layer 12, the first GaN layer 13, the second GaN layer 14, and the barrier layer 15. The AlN layer 12, which operates as a buffer layer for the epitaxial growth of the subsequent layers, may have a thickness of 5 to 30 nm.

The first GaN layer 13 has a carbon concentration [C] less than 1×10¹⁶ cm⁻³, which is the detection limit of an ordinary apparatus such as SIMS (Secondary Ion Mass Spectroscopy). The first GaN layer 13 preferably has a thickness at least 100 nm, or further preferably at least 200 nm, from the viewpoint of reducing the pit density; and 300 nm at most. The second GaN layer 14 also has a carbon concentration [C] greater than 2×10¹⁶ cm⁻³. The second GaN layer 14 preferably has a thickness at least 100 nm, or further preferably at least 200 nm, from the viewpoint of reducing the pit density thereof; and 450 nm at most from the viewpoint of reducing the leak current. Two GaN layers, 13 and 14, may have a total thickness at least 300 nm and 1000 nm at most. The total thickness greater than 300 nm effectively reduces the pit density in the GaN layers, 13 and 14, and that less than 1000 nm, or further preferably less than 600 nm, also effectively reduces the leak current.

The barrier layer 15, which is made of nitride semiconductor material, or materials having electron affinity greater than that of the second GaN layer 14, may be made of AlGaN, InAlN, and/or InAlGaN. The barrier layer 15 preferably has a thickness of 10 to 30 nm.

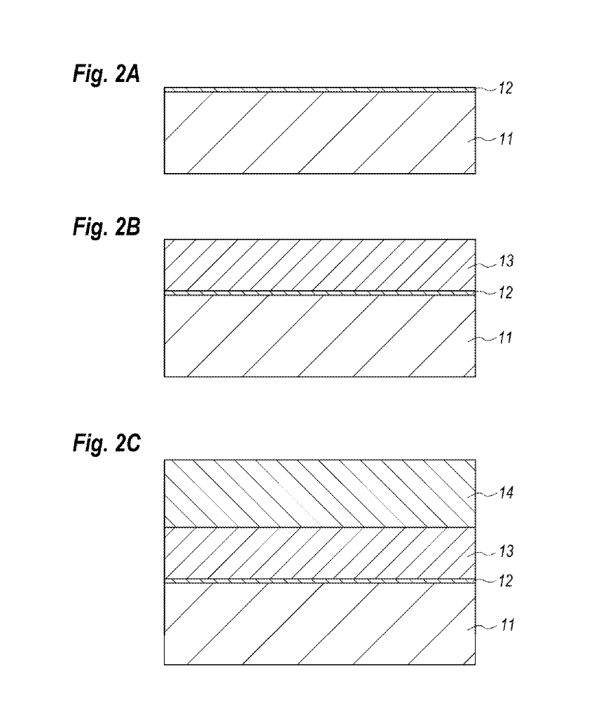

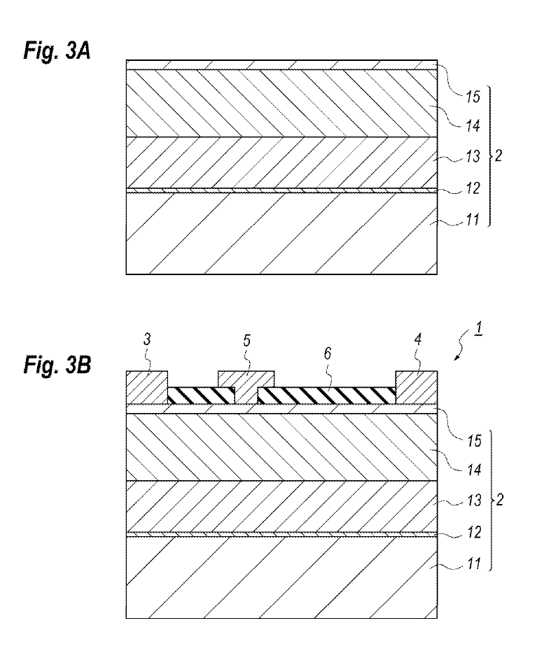

Next, a process of producing the HEMT 1 according to an embodiment of the present application will be described. FIGS. 2A to 3B show processes of the HEMT shown in FIG. 1.

The process first grows the AlN buffer layer 12 on the substrate 11 by, for instance, organic metal vapor phase epitaxy (OMVPE) technique. Source materials for the aluminum (Al) and nitride (N) are, for instance, tri-methyl-aluminum (TMA) and ammonia (NH₃) are selected. The epitaxial growth of the AlN buffer layer 11 is down under conditions of 1050 to 1200° C. and 50 to 120 Torr, for the growth temperature and the grown pressure respectively.

Next, the process grows the first GaN layer 13 on the AlN layer 12 by, for instance, the OMVPE technique under conditions of: sources for the first GaN layer 13 are tri-methyl-gallium (TMG) and ammonia (NH₃) for gallium (Ga) and nitride (N), respectively; the growth temperature higher than 1050° C. but lower than 1200° C.; and the growth pressure higher than 125 Torr but lower than 200 Torr. The growth temperature higher than 1090° C. or the growth pressure higher than 150 Torr is inevitable to grow the first GaN layer 13. That is, when the growth temperature lower than 1090° C., the growth pressure higher than 150 Torr is necessary. On the other hand, when the growth pressure is lower than 150 Torr, the grown temperature higher than 1090° C. is inevitable. The first GaN layer grown under those conditions may lower the carbon concentration [C] but increase the silicon concentration [Si] and the oxygen concentration [O].

Next, the process grows the second GaN layer 14 on the first GaN layer 13 by the OMVPE technique, which is illustrated in FIG. 2C under the conditions of: the source materials of TMG and NH3 for gallium (Ga) and nitride (N), respectively; the growth temperature higher than 1050° C. but lower than 1200° C.; and the growth pressure higher than 50 Torr but lower than 150 Torr.

When the growth temperature for the first GaN layer 13 is higher than 1090° C., the growth temperature of the second GaN layer 14 may be set to be lower than the former growth temperature (1090° C.) and to have a difference at least 40° C. Under such conditions, the growth pressure for the second GaN layer 14 may be equal to that of the first GaN layer 13, or may be different from that of the first GaN layer 13. That is, when the growth temperature of the first GaN layer 13 is higher than 1090° C., the process is unnecessary to take into account of the growth pressure of the second GaN layer 14, exactly, a variation from the growth pressure of the first GaN layer 13. On the other hand, when the growth pressure for the first GaN layer 13 is higher than 150 Torr, the growth pressure for the second GaN layer 14 may be set to be lower than the growth pressure for the first GaN layer 13 and to have a difference at least 50 Torr. That is, the growth pressure for the second GaN layer 14 is set to be at least 50 Torr lower than that for the first GaN layer 13. For such conditions, the growth temperature of the second GaN layer 14 becomes independent of the growth temperature of the first GaN layer 13. In summary, the process may grow the second GaN layer 14 under a condition of, the growth temperature thereof is at least 40° C. lower than that for the growth of the first GaN layer 13 or the growth pressure is at least 50 Torr lower than that for the first GaN layer 13.

The process may grow the barrier layer 15 on the second GaN layer 14 by the OMVPE technique, as shown in FIG. 3A, as the sources of TMG , TMA, and NH3 for gallium (Ga), aluminum (Al), and nitride (N), respectively. Thus, the semiconductor layers 2 of the AlN layer 12, the first GaN layer, the second GaN layer, and the barrier layer 15 sequentially grown on the substrate 11 is completed. Then, as illustrated in FIG. 3B, the source electrode 3, the drain electrode 4, the gate electrode 5, and the passivation film 6 are patterned on the barrier layer 15. Thus, a HEMT 1 may be completed.

The HEMT 1 produced by thus described process, which includes the semiconductor layers 2, provides the first GaN layer 13 on the AlN buffer layer 12. The first GaN layer 13, in particular, a portion of the first GaN layer 13 close to the AlN buffer layer 12, for instance, within a range of 200 nm close to the AlN buffer layer 12, may be affected in physical properties thereof by the AlN buffer layer 12. For instance, the Fermi level, resultantly, the band diagram of the first GaN layer 13 in the region closer to the AlN buffer layer 12 may be pinned to that in the AlN buffer layer 12, which may have the first GaN layer 13 to be independent of the carbon concentration [C], and the leak current of the HEMT 1 becomes dull to the carbon concentration [C]. Thus, even when the growth conditions for the first GaN layer 13 are set so as to reduce the pit density, which means that the carbon concentration [C] become less than 1×10¹⁶ cm⁻³, the increase of the leak current in the HEMT 1 may be suppressed.

On the other hand, the second GaN layer 14 is substantially free from, or independent of, the AlN buffer layer 12 because the first GaN layer 13 is inserted with respect to the AlN buffer layer 12. The band diagram of the second GaN layer 14 in the Fermi level thereof is not pinned to that of the AlN buffer layer 12. The leak current in the second GaN layer 14 depends on, or is strongly affected by the carbon concentration [C] thereof. Accordingly, setting the growth conditions for the second GaN layer 14 so as to reduce the leak current therein by increasing the carbon concentration [C] higher than 2×10¹⁶ cm⁻³, the leak current in the second GaN layer 14 may be effectively reduced. Because the second GaN layer 14 is grown on the first GaN layer 13 whose growth conditions are set so as to decrease the pit density, the second GaN layer 14 may also suppress the pits. Thus, the HEMT 1 of the present embodiment may enable the suppression of the leak current and the increase of the pit density.

A preferable condition for the first GaN layer 13 to reduce the pit density and another preferable condition for the second GaN layer 14 to reduce the leak current are (1) the growth temperature of the first GaN layer 13 is at least 40 ° C. higher than that for the second GaN layer 14, or (2) the growth pressure for the first GaN layer is at least 50 Torr higher than that for the second GaN layer 14. Choosing one of above two conditions, the HEMT 1 produced by thus explained process shows not only the reduction of the pit density but the reduction of the leak current thereof.

The first GaN layer 13 preferably has a thickness greater than 100 nm, which effectively reduces the pit density in the first GaN layer and also the second GaN layer 14. Also, the second GaN layer 14 preferably has a thickness greater than 200 nm, which effectively reduces the leak current of the HEMT 1.

A HEMT and a method of producing the HEMT are not restricted to those described above, and various changes and/or modifications are possible. For instance, a duplicate condition is available where the growth temperature for the first GaN layer 13 is set at least 40° C. higher than that for the second GaN layer 14 simultaneously with the growth pressure for the first GaN layer 13 at least 50 Torr higher than that for the second GaN layer 14. Such a superposed condition may further reduce the pit density appearing in the surface of the HEMT 1.

Also, the HEMT 1, or the semiconductor layers 2 may provide other semiconductor layers in addition to the substrate 11, the AlN layer 12, the first GaN layer, the second GaN layer, and the barrier layer 15. For instance, the semiconductor layers 2 may provide a cap layer on the top thereof, namely, on the surface of the barrier layer 15.

Next, some practical embodiment will be described; but the present invention is not limited to those embodiment.

The first to fifth embodiment of the semiconductor layers have respective thickness in the first GaN layer and the second GaN layer; but other arrangements are common to those embodiment. The first to fifth embodiment had a buffer layer made of AlN grown on the SiC substrate by the OMVPE technique. The growth conditions were (1) the sources were TMA and NH3 for aluminum (Al) and nitride (N), respectively, (2) the growth temperature was 1100 ° C., and (3) the grown pressure was 125 Torr. Then, the first GaN layer was grown on the AlN layer also by the OMVPE technique and the conditions of: the TMG and NH₃ for the sources of gallium (Ga) and nitride (N), respectively, the growth temperature of 1090° C., and the growth pressure of 125 Torr. The second GaN layer was next grown on the first GaN layer also by the OMVPE technique under the conditions of: the TMG and NH3 for the sources of gallium (Ga) and nitride (N), the growth temperature of 1050° C., which is 40° C. lower than that for the first GaN layer, and the growth pressure of 125 Torr equal to that for the first GaN layer. Finally, an AlGaN layer was grown on the second GaN layer by the OMVPE technique under the conditions of: the TMA, TMG, and NH3 for the sources of aluminum (Al), gallium (Ga), and nitride (N), respectively, the growth temperature of 1050° C., and the growth pressure of 125 Torr. The AlN buffer layer and the AlGaN layer had thicknesses of 15 nm and 20 nm, respectively, which were common to the first to fifth embodiment. The table below lists the thicknesses of the first GaN layer and the second GaN layer, where the first to fourth embodiment had a total thickness of 500 nm for the first and second GaN layers but the fifth embodiment had another total thickness of 400 nm.

The sixth to tenth embodiment evaluated the growth pressure. That is, the sixth to tenth embodiment provided the first GaN layer grown under the conditions of: 200 Torr in the growth pressure and 1050° C. in the growth temperature. But other conditions including the conditions to grow the second GaN layer, the AlN buffer layer and the AlGaN barrier layer were common to those described above. That is, the growth pressure for the first GaN layer was 75 Torr higher than that for the second GaN layer, but the growth temperature for the first GaN layer is same with the growth temperature of the second GaN layer. Also, thicknesses of the AlN layer and the AlGaN layer were equal to that of the first to fifth embodiment. The thicknesses of the first GaN layer and those of the second GaN layer are listed in the table below.

The table blow also lists the evaluation for conventional arrangements, that is, the GaN layer provided on the AlN layer was the single layer. The GaN layer in the conventional arrangements had a thickness of 500 nm, which was equal to the first to fourth and sixth to ninth embodiment, and 800 nm thicker than the total thicknesses for all embodiment.

| | comparison | | embodiment | | | | |
|---|---|---|---|---|---|---|---|
| | 1 | 2 | 1 | 2 | 3 | 4 | 5 |
| thickness of | | | | | | | |
| 1^{st} GaN layer | — | — | 200 | 100 | 50 | 300 | 100 |
| (nm) | | | | | | | |
| 2^{nd} GaN layer | 800 | 500 | 300 | 400 | 450 | 200 | 300 |
| (nm) | | | | | | | |
| pit density (cm⁻²) | 13 | 4000 | 12 | 27 | 345 | 5 | 34 |
| leak current | 10 | 0.1 | 0.3 | 0.2 | 0.08 | 0.5 | 0.1 |
| (μA/mm) | | | | | | | |

| | embodiment | | | | |
|---|---|---|---|---|---|
| | 6 | 7 | 8 | 9 | 10 |
| thickness of | | | | | |
| 1^{st} GaN layer (nm) | 200 | 100 | 50 | 300 | 100 |
| 2^{nd} GaN layer (nm) | 300 | 400 | 450 | 200 | 300 |
| pit density (cm⁻²) | 11 | 31 | 417 | 3 | 37 |
| leak current (μA/mm) | 0.3 | 0.1 | 0.07 | 0.6 | 0.1 |

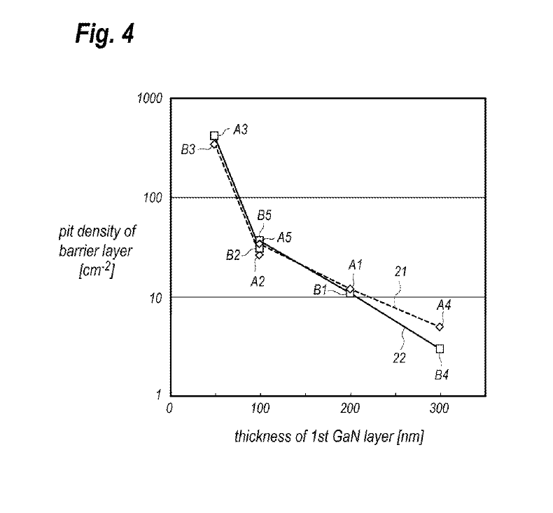

FIG. 4 shows a relation of the pit density appearing in a surface of the AlGaN barrier layer, which was measured by a light microscope, Olympus MX50, against the thickness of the first GaN layer, where pits having diameters greater than 0.2 μm was counted for one square centimeters. Behaviors A1 to A5 denoted by diamonds correspond to the first to fifth embodiment, while, other behaviors B1 to B5 denoted by squares correspond to the sixth to tenth embodiment.

When the GaN layer in the comparable example in the table above has a thickness of 500 nm, the pit density in the barrier layer became 4000 cm⁻², exactly, exceeding 4000 cm⁻²; and 13 cm⁻² for the thickness of 800 nm. Thus, a GaN layer with an enough thickness may bury pits cased during the epitaxial growth, and the surface pit density of the barrier layer may be effectively reduced. The first to fourth, and sixth to ninth embodiment of the present invention, where the total thickness of the first and second GaN layers was 500 nm, the observed pit density was 417 cm⁻² of the eighth embodiment in a maximum. When the first GaN layer had thicknesses greater than 100 nm, the observed pit density was less than 50 cm⁻², and the pit density of 37 cm⁻² for the tenth embodiment was a maximum. Thus, setting the total thickness of the first and second GaN layers was 500 nm, the pit density observed in the barrier layer grown on the second GaN layer decreases, explicitly less than that observed in the second comparable example having the signal GaN layer with a thickness of 500 nm. Also, when the first GaN layer had a thickness greater than 100 nm, the pit density drastically reduces; and the pit density decreased as the thickness of the first GaN layer increased.

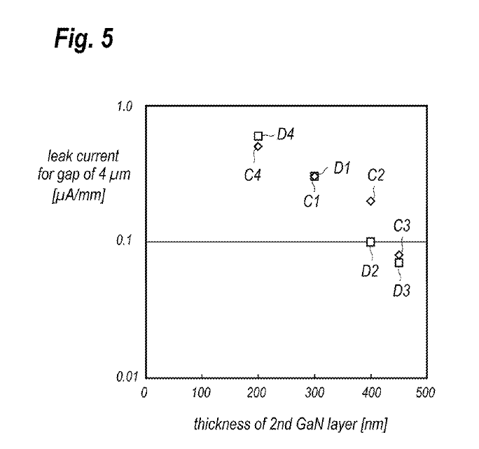

FIG. 5 shows a leak current of the second GaN layer against the thickness thereof The leak currents were measured between two electrodes with a gap of mom and a width of 200 μm under a bias of 100 V. The electrodes, which were made of metal stack of titanium (Ti) and nickel (Ni), were formed on the barrier layer. In FIG. 5, the horizontal axis corresponds to a thickness of the second GaN layer. The second GaN layer or the GaN mono layer with a thickness of 500 nm showed the leak current of 0.1 μA/mm. On the other hand, the GaN mono layer with a thickness of 800 nm showed the leak current of 10 μA/mm, namely, two digits greater than the former. Thus, a thicker GaN layer increases the leak current. On the other hand, the first to fourth and sixth to ninth embodiment where the total thickness of the first and second GaN layers was 500 nm, showed a maximum leak current of 0.6 μA/mm (the ninth embodiment), and a minimum was 0.07 μA/mm (the second embodiment). Thus, comparing the first to fourth and the sixth to ninth embodiment, where the total thickness of the first and second GaN layers was 500 nm, with the second comparable example having the single GaN layer with a thickness of 500 nm; the leak currents were comparable to each other but the pit density appearing in the surface of the barrier layer explicitly reduced. Also, as the thickness of the second GaN layer increased, the leak current decreased.

While particular embodiment of the present invention have been described herein for purposes of illustration, many modifications and changes will become apparent to those skilled in the art. Accordingly, the appended claims are intended to encompass all such modifications and changes as fall within the true spirit and scope of this invention.

I claim:

1. A high electron-mobility transistor (HEMT), comprising:
a buffer layer provided on a substrate, the buffer layer being made of aluminum nitride (AlN); and
a channel layer including a first semiconductor layer and a second semiconductor layer, the first semiconductor layer being configured to be provided on the buffer layer, to be made of gallium nitride (GaN) and to have a carbon concentration less than 1×10¹⁶ cm⁻³, the second semiconductor layer being configured to be provided on the first semiconductor layer, to be made of GaN and to have a carbon concentration greater than 2×10¹⁶ cm⁻³,
wherein the first semiconductor layer and the second semiconductor layer have a total thickness greater than 400 nm but less than 1000 nm.

2. The HEMT of claim 1, wherein the first semiconductor layer has a thickness greater than 100 nm.

3. The HEMT of claim 1, wherein the second semiconductor layer has a thickness greater than 200 nm.

4. The HEMT of claim 1, further including a barrier layer provided on the second semiconductor layer, the barrier layer being made of aluminum-gallium-nitride (AlGaN).

5. A method of producing a high-electron mobility transistor (HEMT) comprising steps of:
growing a buffer layer made of aluminum nitride (AlN) on a substrate;
growing a first semiconductor layer on the buffer layer at a first temperature and a first pressure, the first semiconductor layer being made gallium nitride (GaN); and
growing a second semiconductor layer on the first semiconductor layer at the first temperature but a second pressure at least 50 Torr less than the first pressure, the second semiconductor layer being made of GaN, the first semiconductor layer and the second semiconductor layer having a total thickness greater than 400 nm but less than 1000 nm.

6. The method of claim 5, wherein the step of growing the first semiconductor layer includes a step of growing the first semiconductor layer at a temperature of 1050° C.

7. The method of claim 5, wherein the step of growing the first semiconductor layer includes a step of growing the first semiconductor layer to a thickness greater than 100 nm, and the step of glowing the second semiconductor layer includes a step of growing the second semiconductor layer to a thickness greater than 200 nm.

8. A method of producing a high-electron mobility transistor (HEMT) comprising steps of:
growing a buffer layer made of aluminum nitride (AlN) on a substrate;
growing a first semiconductor layer on the buffer layer at a first temperature and a first pressure, the first semiconductor layer being made gallium nitride (GaN); and
growing a second semiconductor layer on the first semiconductor layer at a second temperature at least 40° C. lower than the first temperature and the first pressure, the second semiconductor layer being made of GaN, the first semiconductor layer and the second semiconductor layer having a total thickness greater than 400 nm but less than 1000 nm.

9. The method of claim 8, wherein the step of growing the first semiconductor layer includes a step of growing the first semiconductor layer to a thickness of at least 100 nm.

10. The method of claim 8, wherein the step of growing the second semiconductor layer includes a step of growing the second semiconductor layer to a thickness of at least 200 nm.

11. The method of claim 8, wherein the step of growing the first semiconductor layer includes a step of growing the first semiconductor layer at the pressure of 125 Torr, and the step of growing the second semiconductor layer includes a step of growing the second semiconductor layer at the pressure of 125 Torr.

12. The method of claim 11, wherein the step of growing the first semiconductor layer includes a step of growing the first semiconductor layer to a thickness of at least 100 nm.

13. The method of claim 11, wherein the step of growing the second semiconductor layer includes a step of growing the second semiconductor layer to a thickness of at least 200 nm.
